(19) United States
(12) Patent Application Publication
(10) Pub. No.: US 2007/0132074 A1
(43) Pub. Date: Jun. 14, 2007

(54) Chip package structure

(76) Inventor: Fan Tsai, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/589,245

(22) Filed: Oct. 30, 2006

(30) Foreign Application Priority Data
Dec. 9, 2005 (TW) 94221552

(51) Int. Cl. H01L 23/495

(52) U.S. Cl. 257/675

(57) ABSTRACT

An improved chip package structure includes a chip carrier, a chip, a plurality of pins, a plurality of leads, a package body and a heat spreader. The chip is fixed on the chip carrier. The leads are electrically connected between the chip and the pins. The package body is packaged outside the chip carrier, the chip and the leads. The heat spreader is disposed in the package body. The heat spreader contacts the chip carrier, and is partially exposed out of a face (top face) of the package body. Heat generated by the chip can thus be transmitted to a heatsink via the chip carrier and the heat spreader so as to discharge a large amount of heat generated by the chip to the outside. The improved chip package structure has a good heat conduction efficiency and an effectively enhanced heat spreading efficiency.

### BACKGROUND OF THE INVENTION

1. Field of the invention

The present invention relates to an improved chip package structure and, more particularly, to an improved chip package structure, which can discharge a large amount of heat generated by a chip to the outside, and has a good heat conduction efficiency and an effectively enhanced heat spreading efficiency.

2. Description of Related Art

In a prior art chip package structure, a chip is adhered onto a chip carrier, and leads are used to electrically connect the chip on the chip carrier to pins by means of wire bonding. Packaging is then performed to form a package body with the chip carrier, the chip and the leads sealed therein. As shown in FIG. 1, a package body 8 is formed outside a chip package structure, and two lines of pins 9 are formed at two opposite sides of the package body 8.

With the swift development of the computer industry, the execution speed of chip becomes faster and faster, and heat generated by a chip becomes more and more. In order to discharge heat generated by a chip to the outside so that the chip can normally operate within the allowable range of temperature, a heatsink is usually installed outside a package body of the chip package structure to help spreading heat. This way of spreading heat, however, heat generated by the chip has to be transmitted to the heatsink via the package body made of plastic material. Therefore, the heat conduction efficiency is poor, resulting in a bad heat spreading efficiency of the heatsink.

Accordingly, the above prior art chip package structure has inconvenience and drawbacks in practical use. The present invention aims to propose an improved chip package structure to solve the above problems in the prior art.

### SUMMARY OF THE INVENTION

An object of the present invention is to provide an improved chip package structure, in which a heat spreader is disposed in a package body and contacts a chip carrier so that heat generated by a chip can be transmitted to the heat spreader. The heat spreader is partially exposed out of the package body to discharge heat generated by the heat to a heatsink so as to discharge heat generated by the heat to the outside. Therefore, the heat conduction efficiency is better, and the heat spreading efficiency can be effectively enhanced.

To achieve the above object, the present invention provides an improved chip package structure, which at least comprises a chip carrier, a chip fixed on the chip carrier, a plurality of pins, a plurality of leads electrically connected between the chip and the pins, a package body packaged outside the chip carrier, the chip and the pins, and a heat spreader disposed in the package body. The heat spreader contacts the chip carrier, and is partially exposed out of a face of the package body.

### BRIEF DESCRIPTION OF THE DRAWINGS

The various objects and advantages of the present invention will be more readily understood from the following detailed description when read in conjunction with the appended drawing, in which:

FIG. 1 is a perspective view of a prior art chip package structure;

FIG. 2 is a front view of a chip package structure of the present invention;

FIG. 3 is a top view of a chip package structure of the present invention;

FIG. 4 is a top view of a chip carrier of the present invention;

FIG. 5 is a top view of a chip and bonding wires of the present invention;

FIG. 6 is a front view of a chip package structure with a heatsink installed according to an embodiment of the present invention; and

FIG. 7 is a front view of a chip package structure with a heatsink installed according to another embodiment of the present invention.

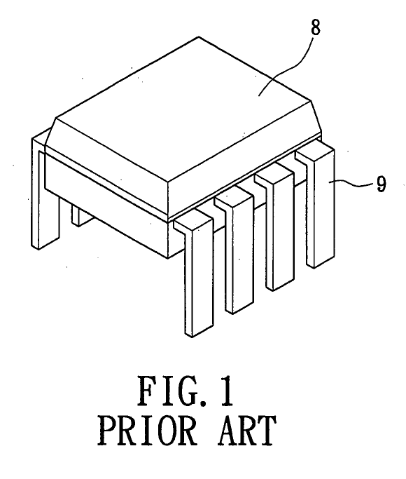

### DETAILED DESCRIPTION OF THE PREFERRED EMBODIMENTS

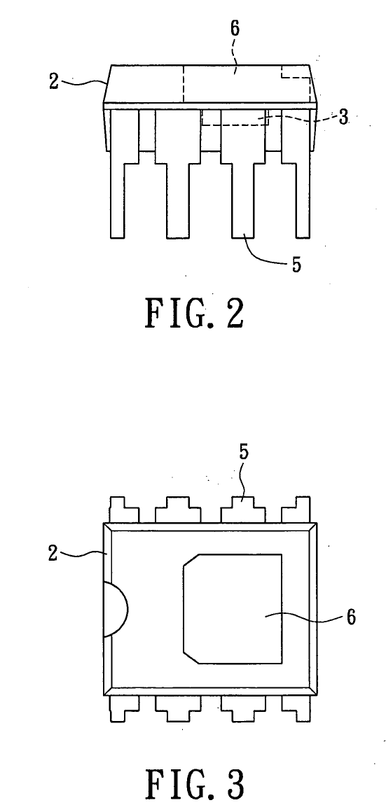

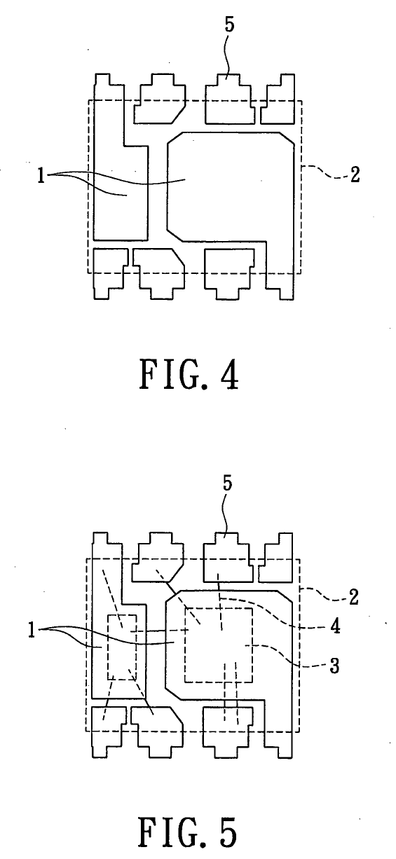

As shown in FIGS. 2 to 5, the present invention provides an improved chip package structure, which at least comprises a chip carrier 1 and a package body 2. The chip carrier 1 is a metal piece made of metal material. At least a chip 3 is adhered and fixed onto the bottom surface of the chip carrier 1. A plurality of leads 4 are then used to electrically connect the chip 3 and a plurality of pins 5 by means of wire bonding. The package body 2 is packaged around the chip carrier 1, the chip 3 and the leads 4 to seal the chip carrier 1, the chip 3 and the leads 4 therein. The pins 5 are disposed at two opposite sides of the package body 2 and extend beyond the package body 2.

A heat spreader 6 is disposed in the package body 2. The heat spreader 6 is made of metal material with good heat conductivity. The heat spreader 6 is fixed in the package body 2. The bottom face of the heat spreader 6 contacts the chip carrier 1. The heat spreader 6 has a partially exposed portion (as shown in FIG. 3, a polygon portion labeled as “6”) that is partially exposed out of the top face of the package body 2. An improved chip package structure of the present invention is thus formed.

The present invention is primarily characterized in that the heat spreader 6 is disposed in the package body 2 and contacts the chip carrier 1 so that heat generated by the chip 3 can be transmitted to the heat spreader 6 via the chip carrier 1. Moreover, because the heat spreader 6 is partially exposed out of the package body 2, heat generated by the chip 3 can further be transmitted to the outside.

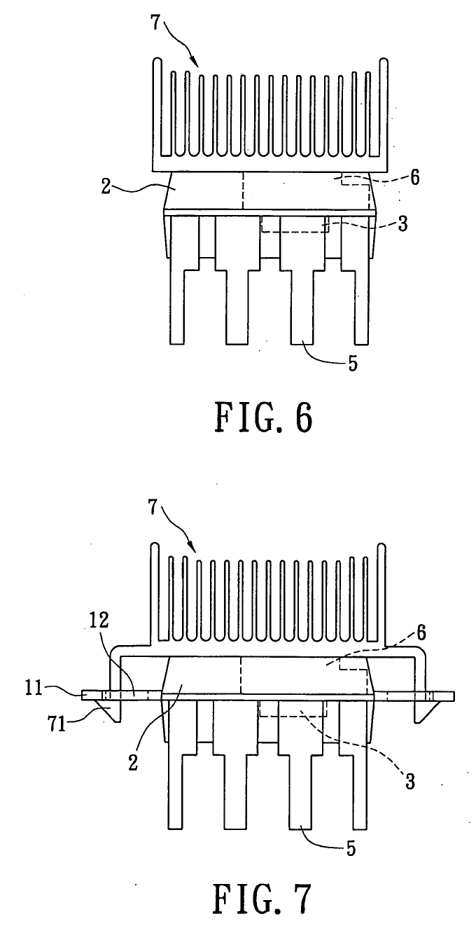

As shown in FIG. 6, when a heatsink 7 is installed outside the package body 2 of the chip package structure to help spreading heat, the exposed portion of the heat spreader 6 can contact the heatsink 7. Heat generated by the chip 3 can be transmitted to the heatsink 7 via the heat spreader 6 to quickly discharge heat generated by the chip 3 to the outside. Therefore, the heat conduction efficiency is better, and the heat spreading efficiency can be effectively enhanced.

Furthermore, as shown in FIG. 7, two extended elements 11 respectively extend outwards from two opposite sides of the chip carrier 1. The two extended elements 11 horizontally protrude out of the two opposite sides of the package body 2. The two extended elements 11 are of flat slab shape. A through hole 12 is disposed on each of the two extended elements 11. Two locking portions 71 respectively extend downwards from two opposite sides of the heatsink 7 to be locked and connected in the two through holes 12 of the two extended elements 11. The heatsink 7 can thus be installed onto the two extended elements 11.

The two extended elements 11 and the chip carrier 1 are made of metal material with good heat conductivity so that heat generated by the chip 3 can be fast transmitted to the heatsink 7 via the chip carrier 1 and the extended elements 11. Therefore, heat generated by the chip 3 can be more quickly discharged to the outside to further enhance the heat spreading efficiency.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. An improved chip package structure at least comprising:
a chip carrier;
a chip fixed on said chip carrier;
a plurality of pins;
a plurality of leads electrically connected between said chip and said pins;
a package body packaged around said chip carrier, said chip and said leads; and
a heat spreader disposed in said package body, said heat spreader contacting said chip carrier and has a partially exposed portion being exposed out of a face of said package body.

2. The improved chip package structure as claimed in claim 1, wherein said chip is disposed on a bottom face of said chip carrier.

3. The improved chip package structure as claimed in claim 1, wherein a heatsink is installed outside said package body, and the partially exposed portion of said heat spreader contacts said heatsink.

4. The improved chip package structure as claimed in claim 3, wherein two extended element respectively extend outwards from two opposite sides of said chip carrier, each of said extended elements has a through hole formed thereon, and two locking portions respectively extend downwards from two opposite sides of said heatsink to be locked and connected in said two through holes of said two extended elements.
